(19) United States
(12) Patent Application Publication
(10) Pub. No.: US 2019/0031919 A1
(43) Pub. Date: Jan. 31, 2019

(54) POLISHING COMPOSITION

(71) Applicant: FUJIMI INCORPORATED, Kiyosu-shi, Aichi (JP)

(72) Inventors: Hisashi TAKEDA, Tualatin, OR (US); Jimmy Erik GRANSTROM, Tualatin, OR (US); Fusayo SAEKI, Tualatin, OR (US)

(73) Assignee: FUJIMI INCORPORATED, Kiyosu-shi, Aichi (JP)

(21) Appl. No.: 16/073,154

(22) PCT Filed: Jan. 13, 2017
(86) PCT No.: PCT/JP2017/001094

§ 371 Date: Jul. 26, 2018

Related U.S. Application Data
(60) Provisional application No. 62/288,340, filed on Jan. 28, 2016.

(51) Int. Cl. C09G 1/02

(52) U.S. Cl. CPC C09G 1/02; H01L 21/3212

(57) ABSTRACT

Described herein are polishing compositions comprising abrasive grains, an additive, and a water-soluble polymer, wherein the compositions have a pH of less than 4.

### TECHNICAL FIELD

The present invention relates generally to the field of polishing compositions.

### BACKGROUND ART

In recent years, a so-called chemical mechanical polishing (CMP) technique for physically polishing and flattening a semiconductor substrate in producing a device is used in accordance with multilayer wiring on a surface of a semiconductor substrate. CMP is a method for flattening the surface of an object to be polished like a semiconductor substrate by using a polishing composition (slurry) containing abrasive grains such as silica, alumina, or ceria, an anti-corrosion agent, a surfactant, or the like. The object to be polished is silicon, polysilicon, silicon oxide film, silicon nitride, a wiring or a plug which consists of metal, or the like.

For example, as a CMP slurry, Patent Literature 1 discloses an aqueous chemical-mechanical polishing composition containing a salt, soluble cerium, carboxylic acid, and fumed silica.

### CITATION LIST

### Patent Literature

Patent Literature 1: Japanese Unexamined Patent Application Publication No. 2001-507739

### SUMMARY OF INVENTION

### Technical Problem

However, according to the aqueous chemical-mechanical polishing composition described in Patent Literature 1, the polishing speed for a substrate can be improved, but there are problems in that scratches on the substrate surface can frequently occur. In particular, prior art polishing compositions have poor storage stability, and thus can develop more scratches on substrate surfaces depending on the storage period.

Accordingly, an object of the present invention is to provide a polishing composition which prevents the occurrence of scratches on substrate surfaces, and can prevent the occurrence of scratches on substrate surfaces even when stored for a long period.

### Solution to Problem

To solve the above problem, the inventors of the present invention conducted intensive studies. As a result, it was found that the above problem can be solved by providing a polishing composition comprising abrasive grains, an additive, and a water-soluble polymer, wherein a ratio of D50(after) to D50(before) is less than 2.0, wherein D50(before) is a value of D50 of particles of the composition when measured before the composition stands for 5 days at 80° C. and D50(after) is a value of D50 of particles of the composition when measured after the composition stands for 5 days at 80° C., and the present invention is completed accordingly.

### Technical Effect

According to the present invention, provided is a polishing composition which prevents the occurrence of scratches on substrate surfaces, and can prevent the occurrence of scratches on substrate surfaces even when stored for a long period.

### DESCRIPTION OF EMBODIMENTS

Hereinbelow, the present invention is described. The present invention is not limited to the following embodiments. In the present description, “X to Y” indicating a range means “X or more and Y or less”. Additionally, unless otherwise specified, operations and measurements of physical properties are carried out at room temperature (20 to 25° C.)/relative humidity 40 to 50% RH. The terms “weight” and “mass”, “% by weight” and “% by mass”, and “parts by weight” and “parts by mass” are used synonymously.

The present invention relates to a polishing composition comprising abrasive grains, an additive, and a water-soluble polymer, wherein a ratio of D50(after) to D50(before) is less than 2.0, wherein D50(before) is a value of D50 of particles of the composition when measured before the composition stands for 5 days at 80° C. and D50(after) is a value of D50 of particles of the composition when measured after the composition stands for 5 days at 80° C.

Incidentally, in this specification, the term “particles” means the concepts including abrasive grains, abrasive grains in the form of monodisperse and as well as abrasive grains in the form of agglomeration. In some embodiments, the particles are abrasive grains.

This construction allows to provide a polishing composition which prevents the occurrence of scratches on substrate surfaces, and can prevent the occurrence of scratches on substrate surfaces even when stored for a long period.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s).

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

As used herein, and unless otherwise described, the term “D50” refers to the median diameter or the median value of the particle size distribution. In some embodiments, “D50” refers to the value of the particle diameter at 50% in the cumulative distribution. In some embodiments, “D50” refers to the median particle size (e.g., diameter) for a volume distribution. As used herein, and unless otherwise described, the term “D90” is the particle size (e.g., diameter) for a volume distribution at which 90% of the distribution lies below this size. Similarly, as used herein, and unless otherwise described, the term “D10” is the particle size (e.g., diameter) for a volume distribution at which 10% of the distribution lies below this size.

Provided herein, in one aspect, are polishing compositions comprising abrasive grains, an additive, and a water-soluble polymer, and having a ratio of D50(after) to D50(before) of less than 2.0, wherein D50(before) is a value of D50 of the particles of the compositions when measured before the compositions are subjected to storage conditions and D50(after) is a value of D50 of the particles of the compositions when measured after the compositions are subjected to storage conditions. In some embodiments, the storage conditions are 5 days at 80° C.

Also provided herein, in another aspect, are polishing compositions comprising abrasive grains, an additive, and a water-soluble polymer, and having a ratio of D50(after) to D50(before) of less than 1.15, wherein D50(before) is a value of D50 of the particles of the compositions when measured before the compositions are subjected to storage conditions and D50(after) is a value of D50 of the particles of the compositions when measured after the compositions are subjected to storage conditions. In some embodiments, the storage conditions are 7 days at 25° C.

Also provided herein, in another aspect, are polishing compositions comprising abrasive grains, an additive, and a water-soluble polymer, wherein the polishing compositions have a pH of less than 4 (in another aspect, a pH of less than 4.0) and comprise no azole-based inhibitor to control nonferrous interconnect removal rate by static etch or other removal mechanisms.

Also provided herein, in another aspect, are polishing compositions comprising abrasive grains, an additive, and a water-soluble polymer, wherein the polishing compositions have a pH of less than 4 (in another aspect, a pH of less than 4.0) and comprise no ammonium salt.

Also provided herein, in another aspect, are polishing compositions comprising abrasive grains, an additive, and a water-soluble polymer, wherein the polishing compositions have a pH of less than 4 (in another aspect, a pH of less than 4.0) and comprise neither citric acid nor citric acid salt.

In some embodiments, the term “D50(before)” means a value of D50 of particles of a freshly made composition described herein. In this specification, the term “a freshly made composition” means compositions which are freshly prepared by mixing components including abrasive grains, an additive and a water-soluble polymer.

In some embodiments, the term “D50(before)” means a value of D50 of particles of a composition described herein when measured before the composition is subjected to storage conditions.

In some embodiments, the term “D50(before)” means a value of D50 of a composition described herein when measured before the composition stands for 5 days at 80° C.

Incidentally, in this specification, the terms “before the compositions are subjected to storage conditions” and “before the composition stands” means immediately after polishing compositions are freshly prepared by mixing components including abrasive grains, an additive and a water-soluble polymer and wherein the term “immediately after” means in some embodiments the time point within 50 mins., in some embodiments the time point within 45 mins., in some embodiments the time point within 30 mins., in some embodiments the time point within 20 mins., in some embodiments the time point within 15 mins., in some embodiments the time point within 10 mins., in some embodiments the time point within 5 mins., in some embodiments the time point within 3 mins. and in some embodiments the time point within 1 min, from the time of mixture of all components and in some embodiments after 50 mins., in some embodiments after 45 mins., in some embodiments after 30 mins., in some embodiments after 20 mins., in some embodiments after 15 mins., in some embodiments after 10 mins., in some embodiments after 5 mins., in some embodiments after 3 mins., and in some embodiments after 1 min., from the time of mixture of all components.

Additionally, “stands for 5 days at 80° C.” means that a polishing composition is freshly prepared by mixing the components including abrasive grains, an additive, and a water-soluble polymer (all the components constitute of the polishing composition are mixed), and stands for 5 days (120 hours) from the point when the mixture is placed in a heater at 80° C. “Stands for 10 days at 55° C.” is interpreted likewise. “Stands for 7 days at 25° C.” means that a polishing composition is freshly prepared by mixing the components including abrasive grains, an additive, and a water-soluble polymer (all the components constitute of the polishing composition are mixed), and stands for 7 days (168 hours) from the point of preparation, wherein no heating in a heater is required because “25° C.” is the reference temperature of measurement in the present description.

In some embodiments, the term “D50(before)” means a value of D50 of particles of a composition described herein when measured before the composition stands for 7 days at 25° C.

In some embodiments, the term “D90(before)” means a value of D90 of particles of a freshly made composition described herein.

In some embodiments, the term “D90(before)” means a value of D90 of particles of a composition described herein when measured before the composition is subjected to storage conditions.

In some embodiments, the term “D90(before)” means a value of D90 of particles of a composition described herein when measured before the composition stands for 5 days at 80° C.

In some embodiments, the term “D90(before)” means a value of D90 of particles of a composition described herein when measured before the composition stands for 7 days at 25° C.

In some embodiments, the term “MV(before)” means a mean value particle size distribution of a freshly made composition described herein.

In some embodiments, the term “MV(before)” means a mean value particle size distribution of particles of a composition described herein when measured before the composition is subjected to storage conditions.

In some embodiments, the term “MV(before)” means a mean value particle size distribution of particles of a composition described herein when measured before the composition stands for 5 days at 80° C.

In some embodiments, the term “MV(before)” means a mean value particle size distribution of particles of a composition described herein when measured before the composition stands for 7 days at 25° C.

In some embodiments, the term “D50(after)” means a value of D50 of particles of a composition described herein when measured after the composition is subjected to storage conditions.

In some embodiments, the term “D50(after)” means a value of D50 of particles of a composition described herein when measured after the composition stands for 5 days at 80° C.

In some embodiments, the term “D50(after)” means a value of D50 of particles of a composition described herein when measured after the composition stands for 7 days at 25° C.

In some embodiments, the term “D90(after)” means a value of D90 of particles of a composition described herein when measured after the composition is subjected to storage conditions.

In some embodiments, the term “D90(after)” means a value of D90 of particles of a composition described herein when measured after the composition stands for 5 days at 80° C.

In some embodiments, the term “D90(after)” means a value of D90 of particles of a composition described herein when measured after the composition stands for 7 days at 25° C.

In some embodiments, the term “MV(after)” means a mean value particle size distribution of particles of a composition described herein when measured after the composition is subjected to storage conditions.

In some embodiments, the term “MV(after)” means a mean value particle size distribution of particles of a composition described herein when measured after the composition stands for 5 days at 80° C.

In some embodiments, the term “MV(after)” means a mean value particle size distribution of particles of a composition described herein when measured after the composition stands for 7 days at 25° C.

As used herein, “storage conditions” means storage at a specified temperature for a specified time period. The specified temperature may be about 20 to about 90° C. The specified temperature includes about 20 to about 80° C., about 20 to about 70° C., about 20 to about 55° C., about 20 to about 40° C., about 25 to about 80° C., about 25 to about 70° C., about 25 to about 55° C., about 25 to about 40° C., about 30 to about 80° C., about 30 to about 70° C., about 30 to about 55° C., or about 30 to about 40° C. In some embodiments, the specified temperature is about 20° C., about 25° C., about 30° C., about 35° C., about 40° C., about 45° C., about 50° C., about 55° C., about 60° C., about 65° C., about 70° C., about 75° C., about 80° C., about 85° C., or about 90° C., or more, including increments therein.

The specified time period may be about 1 hour to about 2 years. The specified time period includes about 1 hour to about 24 hours, about 1 hour to about 48 hours, about 1 hour to about 7 days, about 1 day to about 5 days, about 1 day to about 7 days, about 1 day to about 10 days, about 1 day to about 1 month, about 1 day to about 12 months, about 1 day to about 18 months, about 1 day to about 2 years, about 5 days to about 7 days, about 5 days to about 10 days, about 5 days to about 1 month, about 5 days to about 6 months, about 5 days to about 12 months, about 5 days to about 18 months, about 5 days to about 2 years, about 10 days to about 1 month, about 10 days to about 6 months, about 10 days to about 12 months, about 10 days to about 18 months, and about 10 days to about 2 years. In some embodiments, the specified time period is about 1, 2, 3, 4, 5, 6, 7, 8, 9, 10, 11, 12, 13, 14, 15, 16, 17, 18, 19, 20, 21, 22, 23, or 24 hours, or more, including increments therein. In some embodiments, the specified time period is about 1 day, about 2 days, about 3 days, about 4 days, about 5 days, about 6 days, about 7 days, about 8 days, about 9 days, about 10 days, about 11 days, about 12 days, about 13 days, about 14 days, about 15 days, about 16 days, about 17 days, about 18 days, about 19 days, about 20 days, about 21 days, about 22 days, about 23 days, about 24 days, about 25 days, about 26 days, about 27 days, about 28 days, about 29 days, about 30 days, or about 31 days, or more, including increments therein. In some embodiments, the specified time period is about 1 month, about 2 months, about 3 months, about 4 months, about 5 months, about 6 months, about 7 months, about 8 months, about 9 months, about 10 months, about 11 months, about 12 months, about 13 months, about 14 months, about 15 months, about 16 months, about 17 months, about 18 months, about 19 months, about 20 months, about 21 months, about 22 months, about 23 months, or about 24 months, including increments therein.

The polishing composition may stand (i.e., be stored without stirring) under the storage conditions or may be stirred under the storage conditions. The polishing composition may be in a sealed container or open to ventilation.

In some embodiments, the polishing composition is in a sealed container, standing under the storage conditions.

In some embodiments, the polishing composition is open to ventilation and stirred under the storage conditions. Unless otherwise described, a polishing composition disclosed herein that has been subjected to storage conditions is an aged polishing composition. In some embodiments, particles agglomerate more frequently at higher temperature.

In some embodiments, the polishing composition is superior in that it prevents flocculation even stored under severer conditions, for example, at 80° C. for 5 days, than normal storage conditions.

In some embodiments, the particles of the polishing composition has a ratio of D50(after) to D50(before) of less than 3.0. In some embodiments, the particles of the polishing composition has a ratio of D50(after) to D50(before) of less than 2.9. In some embodiments, the particles of the polishing composition has a ratio of D50(after) to D50(before) of less than 2.8. In some embodiments, the particles of the polishing composition has a ratio of D50(after) to D50(before) of less than 2.7. In some embodiments, the particles of the polishing composition has a ratio of D50(after) to D50(before) of less than 2.6. In some embodiments, the particles of the polishing composition has a ratio of D50(after) to D50(before) of less than 2.5. In some embodiments, the particles of the polishing composition has a ratio of D50(after) to D50(before) of less than 2.4. In some embodiments, the particles of the polishing composition has a ratio of D50(after) to D50(before) of less than 2.3. In some embodiments, the particles of the polishing composition has a ratio of D50(after) to D50(before) of less than 2.2. In some embodiments, the particles of the polishing composition has a ratio of D50(after) to D50(before) of less than 2.1. In some embodiments, the particles of the polishing composition has a ratio of D50(after) to D50(before) of less than 2.0. In some embodiments, the particles of the polishing composition has a ratio of D50(after) to D50(before) of less than 1.9. In some embodiments, the particles of the polishing composition has a ratio of D50(after) to D50(before) of less than 1.8. In some embodiments, the particles of the polishing composition has a ratio of D50(after) to D50(before) of less than 1.7.

In some embodiments, the particles of the polishing composition has a ratio of D90(after) to D90(before) of less than 3.0. In some embodiments, the particles of the polishing composition has a ratio of D90(after) to D90(before) of less than 2.9. In some embodiments, the particles of the polishing composition has a ratio of D90(after) to D90(before) of less than 2.8. In some embodiments, the particles of the polishing composition has a ratio of D90(after) to D90(before) of less than 2.7. In some embodiments, the particles of the polishing composition has a ratio of D90(after) to D90(before) of less than 2.6. In some embodiments, the particles of the polishing composition has a ratio of D90(after) to D90(before) of less than 2.5. In some embodiments, the particles of the composition has a ratio of D90(after) to D90(before) of less than 2.4. In some embodiments, the particles of the polishing composition has a ratio of D90(after) to D90(before) of less than 2.3. In some embodiments, the particles of the polishing composition has a ratio of D90(after) to D90(before) of less than 2.2. In some embodiments, the particles of the polishing composition has a ratio of D90(after) to D90(before) of less than 2.1. In some embodiments, the particles of the polishing composition has a ratio of D90(after) to D90(before) of less than 2.0. In some embodiments, the particles of the polishing composition has a ratio of D90(after) to D90(before) of less than 1.9. In some embodiments, the particles of the polishing composition has a ratio of D90(after) to D90(before) of less than 1.8. In some embodiments, the particles of the polishing composition has a ratio of D90(after) to D90(before) of less than 1.7.

In some embodiments, the particles of the polishing composition has a ratio of MV(after) to MV(before) of less than 3.0. In some embodiments, the particles of the polishing composition has a ratio of MV(after) to MV(before) of less than 2.9. In some embodiments, the particles of the polishing composition has a ratio of MV(after) to MV(before) of less than 2.8. In some embodiments, the particles of the polishing composition has a ratio of MV(after) to MV(before) of less than 2.7. In some embodiments, the particles of the polishing composition has a ratio of MV(after) to MV(before) of less than 2.6. In some embodiments, the particles of the polishing composition has a ratio of MV(after) to MV(before) of less than 2.5. In some embodiments, the particles of the polishing composition has a ratio of MV(after) to MV(before) of less than 2.4. In some embodiments, the particles of the polishing composition has a ratio of MV(after) to MV(before) of less than 2.3. In some embodiments, the particles of the polishing composition has a ratio of MV(after) to MV(before) of less than 2.2. In some embodiments, the particles of the polishing composition has a ratio of MV(after) to MV(before) of less than 2.1. In some embodiments, the particles of the polishing composition has a ratio of MV(after) to MV(before) of less than 2.0. In some embodiments, the particles of the polishing composition has a ratio of MV(after) to MV(before) of less than 1.9. In some embodiments, the particles of the polishing composition has a ratio of MV(after) to MV(before) of less than 1.8. In some embodiments, the particles of the polishing composition has a ratio of MV(after) to MV(before) of less than 1.7.

(Abrasive Grains)

Illustrative abrasive grains include, but are not limited to, silicon oxide (e.g., colloidal silica, fumed silica, or precipitated silica), iron oxide, aluminum oxide, titanium oxide, manganese oxide, cerium oxide, chromium oxide, silicon carbide, diamond, and any combination thereof. In some embodiments, the abrasive grains comprise colloidal silica. In some embodiments, the abrasive grains comprise fumed silica. In some embodiments, the abrasive grains comprise colloidal silica, fumed silica, or a combination thereof.

In some embodiments, the abrasive grains are preferably in the form of a dispersion in a dispersing medium such as water, before the use for the preparation of the polishing composition. In this case, in some embodiments, D10 of the abrasive grains is 10 to 50 nm, in some embodiments, 20 to 45 nm. Additionally, in some embodiments, D50 of the abrasive grains is 30 to 60 nm, and in some embodiments, 35 to 55 nm. Additionally, in some embodiments, D90 of the abrasive grains is 50 to 80 nm, and in some embodiments, 60 to 65 nm. Additionally, in some embodiments, the BET specific surface area of the abrasive grains is 60 to 90 m²/g, and in some embodiments, 70 to 80 m²/g. Additionally, in some embodiments, MV of the abrasive grains is from 30 to 70 nm, and in some embodiments, MV of the abrasive grains is from 40 to 60 nm.

Besides, in some embodiments, the abrasive grains have a ratio of D90 to D10 (D90/D10) of less than 3.0. In some embodiments, the abrasive grains have a ratio of D90 to D10 (D90/D10) of less than 2.9. In some embodiments, the abrasive grains have a ratio of D90 to D10 (D90/D10) of less than 2.8. In some embodiments, the abrasive grains have a ratio of D90 to D10 (D90/D10) of less than 2.7. In some embodiments, the abrasive grains have a ratio of D90 to D10 (D90/D10) of less than 2.6. In some embodiments, the abrasive grains have a ratio of D90 to D10 (D90/D10) of less than 2.5. In some embodiments, the abrasive grains have a ratio of D90 to D10 (D90/D10) of less than 2.4. In some embodiments, the abrasive grains have a ratio of D90 to D10 (D90/D10) of less than 2.3. In some embodiments, the abrasive grains have a ratio of D90 to D10 (D90/D10) of less than 2.2. In some embodiments, the abrasive grains have a ratio of D90 to D10 (D90/D10) of less than 2.1. In some embodiments, the abrasive grains have a ratio of D90 to D10 (D90/D10) of less than 2.0.

In some embodiments, the abrasive grains have a ratio of D90 to D10 (D90/D10) of about 2.0, 2.1, 2.2, 2.3, 2.4, 2.5, 2.6, 2.7, 2.8, 2.9, or 3.0, including increments therein.

In some embodiments, the ratio of D90 to D10 (D90/D10) is measured before the composition is subjected to storage conditions. In some embodiments, the ratio of D90 to D10 (D90/D10) is measured after the composition is subjected to storage conditions. A greater ratio of D90 to D10 represents a broader distribution of particle size which results in a larger surface area of particles. In some embodiments, a larger surface area of particles improves the particle stability in a solution. In some embodiments, a broader distribution of particle size improves the particle stability in a solution.

In some embodiments, the abrasive grains are present in the polishing composition in an amount of at least about 0.1% by mass (wt. %). This includes amounts of at least about 0.2 mass %, about 0.3 mass %, about 0.4 mass %, about 0.6 mass %, about 0.7 mass %, about 0.8 mass %, about 0.9 mass %, about 1.0 mass %, about 1.1 mass %, about 1.2 mass %, about 1.3 mass %, about 1.4 mass %, about 1.5 mass %, about 1.6 mass %, about 1.7 mass %, about 1.8 mass %, about 1.9 mass %, about 2.0 mass %, about 2.1 mass %, about 2.2 mass %, about 2.3 mass %, about 2.4 mass %, about 2.5 mass %, about 2.6 mass %, about 2.7 mass %, about 2.8 mass %, about 2.9 mass %, about 3.0 mass %, about 3.1 mass %, about 3.2 mass %, about 3.3 mass %, about 3.4 mass %, about 3.5 mass %, about 3.6 mass %, about 3.7 mass %, about 3.8 mass %, about 3.9 mass %, about 4.0 mass %, about 4.1 mass %, about 4.2 mass %, about 4.3 mass %, about 4.4 mass %, about 4.5 mass %, about 4.6 mass %, about 4.7 mass %, about 4.8 mass %, about 4.9 mass %, about 5.0 mass %, about 5.1 mass %, about 5.2 mass %, about 5.3 mass %, about 5.4 mass %, about 5.5 mass %, about 5.6 mass %, about 5.7 mass %, about 5.8 mass %, about 5.9 mass %, about 6.0 mass %, about 6.5 mass %, about 7.0 mass %, about 7.5 mass %, about 8.0 mass %, about 8.5 mass %, about 9.0 mass %, about 9.5 mass %, about 10.0 mass %, about 11.0 mass %, about 12.0 mass %, about 13.0 mass %, about 14.0 mass %, or about 15.0 mass %, or more, including increments therein. In some embodiments, the abrasive grains are present in the polishing composition in an amount of about 0.1 mass % to about 10.0 mass %. This includes an amount of about 0.1 mass % to about 9.0 mass %, about 0.1 mass % to about 8.0 mass %, about 0.1 mass % to about 7.0 mass %, about 0.1 mass % to about 6.0 mass %, about 0.1 mass % to about 5.0 mass %, about 0.1 mass % to about 4.0 mass %, about 0.1 mass % to about 3.0 mass %, about 1.0 mass % to about 9.0 mass %, about 1.0 mass % to about 8.0 mass %, about 1.0 mass % to about 7.0 mass %, about 1.0 mass % to about 6.0 mass %, about 1.0 mass % to about 5.0 mass %, about 1.0 mass % to about 4.0 mass %, about 1.0 mass % to about 3.0 mass %, about 2.0 mass % to about 8.0 mass %, about 2.0 mass % to about 6.0 mass %, or about 2.0 mass % to about 4.0 mass %. In some embodiments, the amount of abrasive grains in the polishing composition is about 0.6 mass %, about 0.7 mass %, about 0.8 mass %, about 0.9 mass %, about 1.0 mass %, about 1.1 mass %, about 1.2 mass %, about 1.3 mass %, about 1.4 mass %, about 1.5 mass %, about 1.6 mass %, about 1.7 mass %, about 1.8 mass %, about 1.9 mass %, about 2.0 mass %, about 2.1 mass %, about 2.2 mass %, about 2.3 mass %, about 2.4 mass %, about 2.5 mass %, about 2.6 mass %, about 2.7 mass %, about 2.8 mass %, about 2.9 mass %, about 3.0 mass %, about 3.1 mass %, about 3.2 mass %, about 3.3 mass %, about 3.4 mass %, about 3.5 mass %, about 3.6 mass %, about 3.7 mass %, about 3.8 mass %, about 3.9 mass %, about 4.0 mass %, about 4.1 mass %, about 4.2 mass %, about 4.3 mass %, about 4.4 mass %, about 4.5 mass %, about 4.6 mass %, about 4.7 mass %, about 4.8 mass %, about 4.9 mass %, about 5.0 mass %, about 5.1 mass %, about 5.2 mass %, about 5.3 mass %, about 5.4 mass %, about 5.5 mass %, about 5.6 mass %, about 5.7 mass %, about 5.8 mass %, about 5.9 mass %, about 6.0 mass %, about 6.5 mass %, about 7.0 mass %, about 7.5 mass %, about 8.0 mass %, about 8.5 mass %, about 9.0 mass %, about 9.5 mass %, or about 10 mass %, or more, including increments therein.

In some embodiments, the polishing composition has a pH of less than 7 (in another aspect, a pH of less than 7.0). In some embodiments, the polishing composition has a pH of about 6 or less (in another aspect, a pH of less than 6.0). In some embodiments, the polishing composition has a pH of about 5 or less (in another aspect, a pH of less than 5.0). In some embodiments, the polishing composition has a pH of about 4 or less (in another aspect, a pH of less than 4.0). In some embodiments, the polishing composition has a pH of about 3 or less (in another aspect, a pH of less than 3.0). In some embodiments, the polishing composition has a pH of less than 6 (in another aspect, a pH of less than 6.0). In some embodiments, the polishing composition has a pH of less than 5 (in another aspect, a pH of less than 5.0). In some embodiments, the polishing composition has a pH of less than 4 (in another aspect, a pH of less than 4.0). In some embodiments, the polishing composition has a pH of less than (in another aspect, a pH of less than 3.0).

These embodiments efficiently achieve the intended effect of the present invention. In some embodiments, the polishing composition has a pH of about 6.9, about 6.8, about 6.7, about 6.6, about 6.5, about 6.4, about 6.3, about 6.2, about 6.1, about 6.0, about 5.9, about 5.8, about 5.7, about 5.6, about 5.5, about 5.4, about 5.3, about 5.2, about 5.1, about 5.0, about 4.9, about 4.8, about 4.7, about 4.6, about 4.5, about 4.4, about 4.3, about 4.2, about 4.1, about 4.0, about 3.9, about 3.8, about 3.7, about 3.6, about 3.5, about 3.4, about 3.3, about 3.2, about 3.1, about 3.0, about 2.9, about 2.8, about 2.7, about 2.6, about 2.5, about 2.4, about 2.3, about 2.2, about 2.1, about 2.0, about 1.9, about 1.8, about 1.7, about 1.6, or about 1.5, including increments therein. These embodiments efficiently achieve the intended effect of the present invention.

In some embodiments, the polishing composition has a pH of about 2.0 to about 6.9. In some embodiments, the polishing composition has a pH of about 2.0 to about 6.5. In some embodiments, the polishing composition has a pH of about 2.0 to about 6.0. In some embodiments, the polishing composition has a pH of about 2.0 to about 5.5. In some embodiments, the polishing composition has a pH of about 2.0 to about 5.0. In some embodiments, the polishing composition has a pH of about 2.0 to about 4.5. In some embodiments, the polishing composition has a pH of about 2.0 to about 4.0. In some embodiments, the polishing composition has a pH of about 2.0 to about 3.9. In some embodiments, the polishing composition has a pH of about 2.5 to about 4.0. In some embodiments, the polishing composition has a pH of about 2.5 to about 3.9. In some embodiments, the polishing composition has a pH of about 3.0 to about 4.0. In some embodiments, the polishing composition has a pH of about 3.0 to about 3.9.

In some embodiments, the polishing composition has an electrical conductivity (mS/cm) of about 0.2 to about 1.9. These embodiments efficiently achieve the intended effect of the present invention. In some embodiments, the electrical conductivity (mS/cm) is about 0.3 to about 1.8. In some embodiments, the electrical conductivity (mS/cm) is about 0.4 to about 1.6. In some embodiments, the electrical conductivity (mS/cm) is about 0.5 to about 1.4. In some embodiments, the electrical conductivity (mS/cm) is about 0.6 to about 1.2. These embodiments efficiently achieve the intended effect of the present invention.

(Additive)

In some embodiments, the additive is a polishing accelerator.

In some embodiments, the content of the additive (when two or more additives are contained, their total amount) in the polishing composition is 0.5% by mass or less. In some embodiments, 0.4% by mass or less. In some embodiments, 0.3% by mass or less. In some embodiments, the content of the additive (when two or more additives are contained, their total amount) in the polishing composition is 0.2% by mass or less. In some embodiments, the content of the additive (when two or more additives are contained, their total amount) in the polishing composition is 0.1% by mass or less. These embodiments efficiently achieve the intended effect of the present invention. Additionally, in some embodiments, 0.01% by mass or more. In some embodiments, the content of the additive (when two or more additives are contained, their total amount) in the polishing composition is 0.02% by mass or more. In some embodiments, the content of the additive (when two or more additives are contained, their total amount) in the polishing composition is 0.03% by mass or more. In some embodiments, the content of the additive (when two or more additives are contained, their total amount) in the polishing composition is 0.04% by mass or more. In some embodiments, the content of the additive (when two or more additives are contained, their total amount) in the polishing composition is 0.05% by mass or more. These embodiments efficiently achieve the intended effect of the present invention.

In some embodiments, the additive is carboxylic acid which may have hydroxyl group. These embodiments efficiently achieves the intended effect of the present invention. In some embodiments, the number of the carboxyl group in the carboxylic acid molecule which may have hydroxyl group is two or less. These embodiments efficiently achieves the intended effect of the present invention. In some embodiments, the carboxylic acid which may include a hydroxyl group is lactic acid and/or oxalic acid. These embodiments efficiently achieve the intended effect of the present invention.

In some embodiments, examples of the carboxylic acid containing a hydroxyl group include alpha-hydroxy carboxylic acid, beta-hydroxy carboxylic acid, and gamma-hydroxy carboxylic acid. In some embodiments, the additive comprises an alpha-hydroxy carboxylic acid. Examples of alpha-hydroxy carboxylic acid include, but are not limited to, citric acid, lactic acid, glycolic acid, mandelic acid, malic acid, citramalic acid, isocitric acid, tartaric acid, and tartronic acid or the like. In some embodiments, the additive comprises an alpha-hydroxy carboxylic acid, provided that the alpha-hydroxy carboxylic acid is not citric acid. In some embodiments, the additive comprises lactic acid. In some embodiments, the composition comprises lactic acid but not citric acid. In some embodiments, the composition comprises lactic acid but neither citric acid nor citrate salt. In some embodiments, a polishing composition comprising an alpha-hydroxy carboxylic acid results in higher aluminum and/or aluminum oxide removal compared to a polishing composition without an alpha-hydroxy carboxylic acid. In some embodiments, the polishing composition comprises at least about 0.005% by mass of a carboxylic acid containing a hydroxyl group (preferably alpha-hydroxy carboxylic acid, more preferably lactic acid). In some embodiments, the polishing composition comprises at least about 0.008% by mass of a carboxylic acid containing a hydroxyl group (preferably alpha-hydroxy carboxylic acid, more preferably lactic acid). In some embodiments, the polishing composition comprises at least about 0.01% by mass of a carboxylic acid containing a hydroxyl group (preferably alpha-hydroxy carboxylic acid, more preferably lactic acid). In some embodiments, the polishing composition comprises at least about 0.02% by mass of a carboxylic acid containing a hydroxyl group (preferably alpha-hydroxy carboxylic acid, more preferably lactic acid). In some embodiments, the polishing composition comprises at least about 0.005% by mass to about 0.05% by mass of a carboxylic acid containing a hydroxyl group (preferably alpha-hydroxy carboxylic acid, more preferably lactic acid). This includes about 0.005% by mass to about 0.03% by mass, about 0.005% by mass to about 0.02% by mass, about 0.008% by mass to about 0.03% by mass, about 0.008% by mass to about 0.02% by mass, about 0.01% by mass to about 0.03% by mass, or about 0.01% by mass to about 0.02% by mass. In some embodiments, the polishing composition comprises about 0.005% by mass, about 0.006% by mass, about 0.007% by mass, about 0.008% by mass, about 0.009% by mass, about 0.010% by mass, about 0.011% by mass, about 0.012% by mass, about 0.013% by mass, about 0.014% by mass, about 0.015% by mass, about 0.016% by mass, about 0.017% by mass, about 0.018% by mass, about 0.019% by mass, about 0.020% by mass, about 0.021% by mass, about 0.022% by mass, about 0.023% by mass, about 0.024% by mass, about 0.025% by mass, about 0.026% by mass, about 0.027% by mass, about 0.028% by mass, about 0.029% by mass, about 0.030% by mass, about 0.040% by mass, about 0.050% by mass, about 0.060% by mass, about 0.070% by mass, about 0.080% by mass, about 0.090% by mass, about 0.10% by mass, or more of a carboxylic acid containing a hydroxyl group (preferably alpha-hydroxy carboxylic acid, more preferably lactic acid), including increments therein.

In some embodiments, a carboxylic acid having no hydroxyl group may be contained. In some embodiments, the carboxylic acid having no hydroxyl group is preferably a dicarboxylic acid. In some embodiments, the carboxylic acid having no hydroxyl group is preferably those has a chelating action on a metal, such as oxalic acid, malonic acid, maleic acid, or iminodiacetic acid. In some embodiments, the carboxylic acid having no hydroxyl group (preferably oxalic acid) is present in an amount of at least about 0.005% by mass in the polishing composition. In some embodiments, the carboxylic acid having no hydroxyl group (preferably oxalic acid) is present in the polishing composition in an amount of at least about 0.008% by mass. In some embodiments, the carboxylic acid having no hydroxyl group (preferably oxalic acid) is present in the polishing composition in an amount of at least about 0.01% by mass. In some embodiments, the carboxylic acid having no hydroxyl group (preferably oxalic acid) is present in the polishing composition in an amount of at least about 0.005% by mass to about 0.1% by mass. This includes an amount of about 0.005% by mass to about 0.08% by mass, about 0.005% by mass to about 0.05% by mass, about 0.005% by mass to about 0.03% by mass, about 0.005% by mass to about 0.01% by mass, about 0.007% by mass to about 0.1% by mass, about 0.007% by mass to about 0.08% by mass, about 0.007% by mass to about 0.05% by mass, about 0.007% by mass to about 0.03% by mass, about 0.007% by mass to about 0.01% by mass, about 0.01% by mass to about 0.1% by mass, about 0.01% by mass to about 0.08% by mass, about 0.01% by mass to about 0.05% by mass, or about 0.01% by mass to about 0.03% by mass. In some embodiments, the carboxylic acid having no hydroxyl group (preferably oxalic acid) is present in the polishing composition in an amount of about 0.005% by mass, about 0.006% by mass, about 0.007% by mass, about 0.008% by mass, about 0.009% by mass, about 0.010% by mass, about 0.011% by mass, about 0.012% by mass, about 0.013% by mass, about 0.014% by mass, about 0.015% by mass, about 0.016% by mass, about 0.017% by mass, about 0.018% by mass, about 0.019% by mass, about 0.020% by mass, about 0.021% by mass, about 0.022% by mass, about 0.023% by mass, about 0.024% by mass, about 0.025% by mass, about 0.026% by mass, about 0.027% by mass, about 0.028% by mass, about 0.029% by mass, about 0.030% by mass, about 0.031% by mass, about 0.032% by mass, about 0.033% by mass, about 0.034% by mass, about 0.035% by mass, about 0.036% by mass, about 0.037% by mass, about 0.038% by mass, about 0.039% by mass, about 0.040% by mass, about 0.041% by mass, about 0.042% by mass, about 0.043% by mass, about 0.044% by mass, about 0.045% by mass, about 0.046% by mass, about 0.047% by mass, about 0.048% by mass, about 0.049% by mass, about 0.050% by mass, about 0.055% by mass, about 0.060% by mass, about 0.065% by mass, about 0.070% by mass, about 0.075% by mass, about 0.080% by mass, about 0.085% by mass, about 0.090% by mass, about 0.095% by mass, about 0.10% by mass, about 0.15% by mass, about 0.20% by mass, about 0.25% by mass, about 0.30% by mass, about 0.35% by mass, about 0.40% by mass, about 0.45% by mass, about 0.50% by mass, about 0.55% by mass, about 0.60% by mass, about 0.65% by mass, about 0.70% by mass, about 0.75% by mass, about 0.80% by mass, about 0.85% by mass, about 0.90% by mass, about 0.95% by mass, about 1.00% by mass, or more, including increments therein.

(Water-Soluble Polymer)

In some embodiments, the water-soluble polymer comprises at least one carboxyl group or polysaccharide. These embodiments efficiently achieve the intended effect of the present invention.

In some embodiments, the polysaccharide is a polysaccharide consisting of glucose.

In some embodiments, the polysaccharide consisting of glucose is pullulan, starch dextrin, cyclodextrin, or, dextran. These embodiments efficiently achieve the intended effect of the present invention.

In some embodiments, the repeating unit composing the water-soluble polymer has carboxyl group. These embodiments efficiently achieve the intended effect of the present invention. In some embodiments, the water-soluble polymer comprises a polycarboxylic acid. In some embodiments, the water-soluble polymer comprises a polyacrylic acid. These embodiments efficiently achieve the intended effect of the present invention. In some embodiments, the weight average molecular weight of the water-soluble polymer is preferably 50,000 to 500,000. In some embodiments, 100,000 to 300,000.

The weight average molecular weight uses the value of the weight average molecular weight (in terms of polyethylene glycol) measured by gel permeation chromatography (GPC). The weight average molecular weight is measured with the following apparatus and under following conditions.

GPC instrument: Shimadzu Co., Ltd.

Model: Prominence+ELSD detector (ELSD-LTII)

Column: VP-ODS (Shimadzu Co., Ltd.)

Mobile phase A: MeOH

B: Acetic acid 1% aqueous solution

Detector: ELSD temp. 40° C., Gain 8, N2GAS 350 kPa

Oven temperature: 40° C.

In some embodiments, the polishing composition comprises at least about 0.05 mass % of the water-soluble polymer. In some embodiments, the polishing composition comprises at least about 0.08 mass % of the water-soluble polymer. In some embodiments, the polishing composition comprises about 0.05 mass % to about 0.2 mass % of the water-soluble polymer. This includes about 0.05 mass % to about 0.15 mass %, about 0.05 mass % to about 0.1 mass %, about 0.08 mass % to about 0.2 mass %, or about 0.08 mass % to about 0.15 mass % of the water-soluble polymer. In some embodiments, the polishing composition comprises about 0.05 mass %, about 0.06 mass %, about 0.07 mass %, about 0.08 mass %, about 0.09 mass %, about 0.10 mass %, about 0.11 mass %, about 0.12 mass %, about 0.13 mass %, about 0.14 mass %, about 0.15 mass %, about 0.16 mass %, about 0.17 mass %, about 0.18 mass %, about 0.19 mass %, or about 0.20 mass %, or more, including increments therein, of the water-soluble polymer.

In some embodiments, the polishing composition comprises at least about 0.05 mass % of polyacrylic acid. In some embodiments, the polishing composition comprises at least about 0.08 mass % of polyacrylic acid. In some embodiments, the polishing composition comprises about 0.05 mass % to about 0.2 mass % of polyacrylic acid. This includes about 0.05 mass % to about 0.15 mass %, about 0.05 mass % to about 0.1 mass %, about 0.08 mass % to about 0.2 mass %, or about 0.08 mass % to about 0.15 mass % of polyacrylic acid. In some embodiments, the polishing composition comprises about 0.05 mass %, about 0.06 mass %, about 0.07 mass %, about 0.08 mass %, about 0.09 mass %, about 0.10 mass %, about 0.11 mass %, about 0.12 mass %, about 0.13 mass %, about 0.14 mass %, about 0.15 mass %, about 0.16 mass %, about 0.17 mass %, about 0.18 mass %, about 0.19 mass %, or about 0.20 mass %, or more, including increments therein, of polyacrylic acid.

In some embodiments, the polishing composition further comprises an oxidizing agent. Illustrative oxidizing agents include, but are not limited to, hydrogen peroxide, a persulfate, a perchlorate, a periodate, or a nitratelt.

In some embodiments, the oxidizing agent is present in the polishing composition in an amount of about 0.1 vol. %, about 0.2 vol. %, about 0.3 vol. %, about 0.4 vol. %, about 0.5 vol. %, about 0.6 vol. %, about 0.7 vol. %, about 0.8 vol. %, about 0.9 vol. %, about 1.0 vol. %, about 1.1 vol. %, about 1.2 vol. %, about 1.3 vol. %, about 1.4 vol. %, about 1.5 vol. %, about 1.6 vol. %, about 1.7 vol. %, about 1.8 vol. %, about 1.9 vol. %, about 2.0 vol. %, about 2.1 vol. %, about 2.2 vol. %, about 2.3 vol. %, about 2.4 vol. %, about 2.5 vol. %, about 2.6 vol. %, about 2.7 vol. %, about 2.8 vol. %, about 2.9 vol. %, or 3.0 vol. %, or more, including increments therein. In some embodiments, hydrogen peroxide is present in the polishing composition in an amount of about 0-about 3.0 vol. %. Inclusion of the oxidizing agent may lead to more uniform and/or higher removal rate.

Illustrative azole-based inhibitors include, but are not limited to, benzotriazoles, benzimidazoles, triazoles, imidazole, tolyltriazole, and any combination thereof. Specific examples include, but are not limited to, 1-(1,2-dicarboxyethyl)benzotriazole, 1-[N,N-bis(hydroxyethyl)aminomethyl]benzotriazole, 1-(2,3-dihydroxypropyl)benzotriazole, and 1-(hydroxymethyl)benzotriazole.

Too high a level of viscosity may cause non-uniformity issues in polishing a substrate. In some embodiments, the polishing composition has a viscosity of about 50 cps or less. In some embodiments, the polishing composition has a viscosity of about 10 cps or less. In some embodiments, the polishing composition has a viscosity of about 5 cps or less. In some embodiments, the polishing composition has a viscosity of about 2 cps or less. In some embodiments, the polishing composition has a viscosity of about 0.1 cps, about 0.2 cps, about 0.3 cps, about 0.4 cps, about 0.5 cps, about 0.6 cps, about 0.7 cps, about 0.8 cps, about 0.9 cps, about 1.0 cps, about 1.1 cps, including increments therein. In some embodiments, the method for measuring the viscosity is as follows.

The viscosity was measured using a viscometer (Cannon-Fenske, Shibata Scientific Technology Ltd.), and calculated according to the following formula (the viscosity is measured at 25° C.)

Viscosity=specific gravity×outflow time

In some embodiments, the polishing composition comprising abrasive grains, an additive, and a water-soluble polymer, wherein the polishing composition has a pH of less than 4 (in another aspect, a pH of less than 4.0) and does not comprise ammonium salt, citric acid, and/or citrate salt.

In some embodiments, the polishing composition comprising abrasive grains, an additive, and a water-soluble polymer, wherein the polishing composition has a pH of less than 4 (in another aspect, a pH of less than 4.0) and does not comprise azole-based inhibitor and/or ammonium salt.

In some embodiments, the polishing composition comprising abrasive grains, an additive, and a water-soluble polymer, wherein the polishing composition has a pH of less than 4 (in another aspect, a pH of less than 4.0) and does not comprise azole-based inhibitor, citric acid, and/or citrate salt.

In some embodiments, the polishing composition comprising abrasive grains, an additive, and a water-soluble polymer, wherein the polishing composition has a pH of less than 4 and does not comprise azole-based inhibitor, ammonium salt, citric acid, and/or citrate salt.

In some embodiments, the polishing composition consists essentially of colloidal silica, lactic acid, oxalic acid, polyacrylic acid and a dispersing medium (solvent), wherein the polishing composition has a pH of less than 4 (in another aspect, a pH of less than 4.0).

These embodiments efficiently achieve the intended effect of the present invention. In further embodiments, the polishing composition is devoid of at least one kind selected from the group consisting of an ammonium salt, citric acid and/or citrate salt, and an azole-based inhibitor. In some embodiments, the pH of the polishing composition is less than 3 (in another aspect, a pH of less than 3.0). These embodiments efficiently achieve the intended effect of the present invention.

Also provided herein, in another aspect, are methods to prepare a polishing composition described herein.

The polishing compositions described herein may be used in any suitable manner. For examples, the compositions may be shipped for use in their “wet” state, for example, due to their stability. In some embodiments, the compositions are transported by rail or road. The compositions may be dried and used as they customarily are used by those skilled in the art. In some embodiments, the compositions described herein are used for polishing applications.

In some embodiments, use of a polishing composition described herein results in minimal scratching of silicon wafer (in some embodiments, silicon wafer wholly covered by an oxide film).

In some embodiments, minimal scratching means less than about 250 or less of scratches. This includes minimal scratching of less than about 240, about 230, about 220, about 210, about 200, about 195, about 180, about 175, about 170, about 165, about 160, about 155, about 150, about 145, about 140, about 135, about 130, about 125, about 120, about 115, about 110, about 105, about 100, about 95, about 90, about 85, about 80, about 75, about 70, about 65, about 60, about 55, about 50, about 45, about 40, about 35, about 30 scratches, including increments therein. In some embodiments, the polishing composition is freshly made or aged under storage conditions.

In some embodiments, use of a freshly made polishing composition described herein or its aged counterpart results in minimal scratching of silicon wafer (in some embodiments, silicon wafer wholly covered by an oxide film). In some embodiments, a level of minimal scratching of a silicon wafer from the use of an aged polishing composition is preferred to be similar to a level of scratching of a silicon wafer from the use of a freshly made polishing composition. More concretely, it means that the difference between a number of scratch due to use of a freshly made polishing composition and a number of scratch due to use of an aged polishing composition is 800% or less on the basis of a number of scratch due to use of a freshly made polishing composition.

That is to say, if a number of scratch due to use of a freshly made polishing composition is 100 and a number of scratch due to use of an aged polishing composition is 900, the difference is 800%. If a number of scratch due to use of a freshly made polishing composition is 100 and a number of scratch due to use of an aged polishing composition is 100, the difference is 0%. In some embodiments, the difference includes about 700% or less, about 600% or less, about 500% or less, about 400% or less, about 300% or less, about 200% or less, about 100% or less, about 90% or less, about 80% or less, about 70% or less, about 60% or less, about 50% or less, about 40% or less, about 30% or less, about 24% or less, 23% or less, 22% or less, 21% or less, 20% or less, 19% or less, 18% or less, 17% or less, 16% or less, 15% or less, 14% or less, 13% or less, 12% or less, 11% or less, 10% or less, 9% or less, 8% or less, 7% or less, 6% or less, 5% or less, 4% or less, 3% or less, 2% or less, 1% or less, 0%.

(Other Components)

In some embodiments, the polishing composition may further comprise, as necessary, other components such as a metal anticorrosive, an antiseptic agent, an antifungal agent, a reducing agent, a surfactant, or an organic solvent for solving slightly soluble organic substances.

(Method of Making Polishing Composition)

In some embodiments, the polishing composition can be made by mixing the components composing the polishing composition.

The mixing method is not particularly limited; for example, abrasive grains, additives, and a water-soluble polymer are mixed under stirring in a dispersing medium. The order of addition of the abrasive grains, additives, and water-soluble polymer is not limited. However, in order to secure the maximum solubility of the components in the composition, and in order to minimize the chemical change during preparation of the composition, the abrasive grains are preferably added at the end. The temperature during mixing these components is not particularly limited, but is preferably 10 to 40° C., and may be increased thereby increasing the rate of dissolution. Additionally, the mixing time is also not particularly limited.

The dispersing medium preferably comprises water. At that time, from the viewpoint of preventing the inhibition of the actions by other components, the water preferably comprises minimum impurities; specifically, the water is preferably pure water, ultrapure water, or distilled water from which impurity ions have been removed with an ion exchange resin, and impurities have been removed by filtration.

(Polishing Method)

The present invention provides a polishing method for polishing the object to be polished using the above polishing composition, or using a polishing composition obtained by the above making method.

The polishing instrument may be a common polishing instrument which is equipped with a holder for holding a substrate having the object to be polished and a motor whose rotation speed can be changed, and has a polishing table to which a polishing pad (polishing cloth) can be attached.

The polishing pad may be, for example a common nonwoven fabric, polyurethane, or a porous fluorocarbon resin, without particular limitation. The polishing pad is preferably roove-processed for retaining the polishing liquid.

The polishing conditions are also not particularly limited; for example, the rotation speeds of the polishing table and head are each independently preferably 10 to 500 rpm, and the pressure applied to the substrate having the object to be polished (polishing pressure) is preferably 0.5 to 10 psi. The method for feeding the polishing composition to the polishing pad is also not particularly limited; for example, continuous feeding using a pump is used. The feeding amount is not limited, but the surface of the polishing pad is preferably always covered by the polishing composition of the present invention.

The polishing composition according to the present invention may be one-liquid type, or a multi-liquid type such as a two-liquid type, wherein a portion or whole of the polishing composition is mixed at any mixing ratio. Additionally, when a polishing instrument having a plurality of channels for feeding the polishing composition, two or more polishing compositions, which have been prepared in advance, may be used thereby mixing the polishing compositions on the polishing instrument.

Additionally, the polishing composition according to the present invention may be in the form of a stock solution, and may be prepared by diluting the stock solution of the polishing composition with water. When the polishing composition is two-liquid type, the order of mixing and dilution is arbitrary. For example, one composition is diluted with water, and then mixed with the other composition; the mixture is diluted with water concurrently with mixing; or the mixed polishing composition is diluted with water.

Additionally, in the present invention, the following embodiments are also provided.

(1) A polishing composition comprising abrasive grains, a polishing accelerator, and a water-soluble polymer, and having a ratio of D50(after) to D50(before) of less than 2.0, wherein D50(before) is a value of D50 of the composition when measured before the composition stands for 5 days at 80° C. and D50(after) is a value of D50 of the composition when measured after the composition stands for 5 days at 80° C.

(2) The polishing composition of (1), further having a ratio of D90(after) to D90(before) of less than 2.0, wherein D90(before) is a value of D90 of the composition when measured before the composition stands for 5 days at 80° C. and D90(after) is a value of D90 of the composition when measured after the composition stands for 5 days at 80° C.

(3) The polishing composition of (1) or (2), further having a ratio of MV(after) to MV(before) of less than 2.0, wherein MV(before) is the mean value particle size distribution of the composition when measured before the composition stands for 5 days at 80° C. and MV(after) is the mean value particle size distribution of the composition when measured after the composition stands for 5 days at 80° C.

(4) A polishing composition comprising abrasive grains, a polishing accelerator, and a water-soluble polymer, and having a ratio of D50(after) to D50(before) of less than 1.15, wherein D50(before) is a value of D50 of the composition when measured before the composition stands for 7 days at 25° C. and D50(after) is a value of D50 of the composition when measured after the composition stands for 7 days at 25° C.

(5) The polishing composition of (4), further having a ratio of D90(after) to D90(before) of less than 1.05, wherein D90(before) is a value of D90 of the composition when measured before the composition stands for 7 days at 25° C. and D90(after) is a value of D90 of the composition when measured after the composition stands for 7 days at 25° C.

(6) The polishing composition of (4) or (5), further having a ratio of MV(after) to MV(before) of less than 1.15, wherein MV(before) is the mean value particle size distribution of the composition when measured before the composition stands for 7 days at 25° C. and MV(after) is the mean value particle size distribution of the composition when measured after the composition stands for 7 days at 25° C.

(7) The polishing composition of any one of (1)-(6) wherein the composition has a pH of less than 4.

(8) The polishing composition of (7), wherein the composition has a pH of less than 3.

(9) The polishing composition of any one of (1)-(8), wherein the polishing accelerator comprises an alpha-hydroxy carboxylic acid.

(10) The polishing composition of (9), wherein the alpha-hydroxy carboxylic acid is lactic acid.

(11) The polishing composition of any one of (1)-(10), wherein the water-soluble polymer comprises at least one carboxylic acid.

(12) The polishing composition of (11) wherein the water-soluble polymer is a polycarboxylic acid.

(13) The polishing composition of (11) or (12), wherein the water-soluble polymer is polyacrylic acid.

(14) The polishing composition of any one of (1)-(13) further comprising oxalic acid.

(15) The polishing composition of any one of (1)-(14) further comprising an oxidizing agent.

(16) The polishing composition of any one of claims (1)-(15), wherein the abrasive grains comprise colloidal silica.

(17) The polishing composition of any one of claims (1)-(16), wherein the abrasive grains have a ratio of D90 to D10 (D90/D10) of less than 3.

(18) The polishing composition of any one of claims (1)-(17), wherein the abrasive grains have a ratio of D90 to D10 (D90/D10) of less than 2.5.

(19) The polishing composition of any one of claims (1)-(18), wherein the abrasive grains have a ratio of D90 to D10 (D90/D10) of less than 2.3.

(20) A polishing composition comprising abrasive grains, a polishing accelerator, and a water-soluble polymer, wherein the polishing composition has a pH of less than 4 and comprises no azole-based inhibitor to control nonferrous interconnect removal rate by static etch or other removal mechanisms.

(21) The polishing composition of (20), wherein the polishing accelerator comprises an alpha-hydroxy carboxylic acid.

(22) The polishing composition of (21), wherein the alpha-hydroxy carboxylic acid is lactic acid.

(23) The polishing composition of any one of (20)-(22), wherein the water-soluble polymer comprises at least one carboxylic acid.

(24) The polishing composition of (23), wherein the water-soluble polymer is a polycarboxylic acid.

(25) The polishing composition of (23) or (24), wherein the water-soluble polymer is polyacrylic acid.

(26) The polishing composition of any one of (20)-(25) further comprising oxalic acid.

(27) The polishing composition of any one of (20)-(26) further comprising an oxidizing agent.

(28) The polishing composition of any one of (20)-(27), wherein the abrasive grains comprise colloidal silica.

(29) The polishing composition of any one of (20)-(28), wherein the abrasive grains have a ratio of D90 to D10 (D90/D10) of less than 3.

(30) The polishing composition of any one of (20)-(29), wherein the abrasive grains have a ratio of D90 to D10 (D90/D10) of less than 2.5.

(31) The polishing composition of any one of (20)-(30), wherein the abrasive grains have a ratio of D90 to D10 (D90/D10) of less than 2.3.

(32) A polishing composition comprising abrasive grains, a polishing accelerator, and a water-soluble polymer, wherein the polishing composition has a pH of less than 4 and comprises no ammonium salt.

(33) The polishing composition of (32), wherein the polishing accelerator comprises an alpha-hydroxy carboxylic acid.

(34) The polishing composition of (33), wherein the alpha-hydroxy carboxylic acid is lactic acid.

(35) The polishing composition of any one of (32)-(34), wherein the water-soluble polymer comprises at least one carboxylic acid.

(36) The polishing composition of (35), wherein the water-soluble polymer is a polycarboxylic acid.

(37) The polishing composition of (35) or (36), wherein the water-soluble polymer is polyacrylic acid.

(38) The polishing composition of any one of (32)-(37) further comprising oxalic acid.

(39) The polishing composition of any one of (32)-(38) further comprising an oxidizing agent.

(40) The polishing composition of any one of (32)-(39), wherein the abrasive grains comprise colloidal silica.

(41) The polishing composition of any one of (32)-(40), wherein the abrasive grains have a ratio of D90 to D10 (D90/D10) of less than 3.

(42) The polishing composition of any one of (32)-(41), wherein the abrasive grains have a ratio of D90 to D10 (D90/D10) of less than 2.5.

(43) The polishing composition of any one of (32)-(42), wherein the abrasive grains have a ratio of D90 to D10 (D90/D10) of less than 2.3.

(44) A polishing composition comprising abrasive grains, a polishing accelerator, and a water-soluble polymer, wherein the polishing composition has a pH of less than 4 and comprises neither citric acid nor citric acid salt.

(45) The polishing composition of (44), wherein the polishing accelerator comprises an alpha-hydroxy carboxylic acid.

(46) The polishing composition of (45), wherein the alpha-hydroxy carboxylic acid is lactic acid.

(47) The polishing composition of any one of (44)-(46), wherein the water-soluble polymer comprises at least one carboxylic acid.

(48) The polishing composition of (47), wherein the water-soluble polymer is a polycarboxylic acid.

(49) The polishing composition of (47) or (48), wherein the water-soluble polymer is polyacrylic acid.

(50) The polishing composition of any one of (44)-(49) further comprising oxalic acid.

(51) The polishing composition of any one of (44)-(50) further comprising an oxidizing agent.

(52) The polishing composition of any one of (44)-(51), wherein the abrasive grains comprise colloidal silica.

(53) The polishing composition of any one of (44)-(52), wherein the abrasive grains have a ratio of D90 to D10 (D90/D10) of less than 3.

(54) The polishing composition of any one of (44)-(53), wherein the abrasive grains have a ratio of D90 to D10 (D90/D10) of less than 2.5.

(55) The polishing composition of any one of (44)-(54), wherein the abrasive grains have a ratio of D90 to D10 (D90/D10) of less than 2.3.

(56) A polishing composition consisting essentially of colloidal silica, lactic acid, oxalic acid, and polyacrylic acid, wherein the polishing composition has a pH of less than 4.

(57) The polishing composition of (56), wherein the polishing composition has a pH of less than 3.

The present invention, thus generally described, will be understood more readily by reference to the following examples, which are provided by way of illustration and are not intended to be limiting of the present invention.

Unless otherwise specified, “%” and “part” respectively means “% by mass” and “parts by mass”. In the following examples, unless otherwise specified, the operations were carried out at room temperature (25° C.)/relative humidity 40 to 50% RH.

### EXAMPLES

### Example 1. Polishing Compositions

Table 1 illustrates five compositions that were prepared. Colloidal silica was added last to ensure that the silica was subject to minimal chemical change during the composition preparation. Compositions were prepared at room temperature with a mixing rate of 300 rpm. Slurry A was prepared by addition of citric acid into water, followed by addition of tri-potassium citrate monohydrate, pullulan, and then colloidal silica A. Slurries B and E were prepared by addition of lactic acid into water, followed by addition of oxalic acid, polyacrylic acid (25 mass % solution), and colloidal silica B. Slurry C was prepared by addition of lactic acid into water, followed by addition of oxalic acid, polyacrylic acid (25 mass % solution), and colloidal silica A. Slurry D was prepared by addition of lactic acid into water, followed by addition of oxalic acid, pullulan, and colloidal silica B.

All the five compositions thus prepared (25° C.) had a viscosity of 1.1±0.02 cps.

TABLE 1

| | | | | | tri-potassium | | pullulan | polyacrylic | | | |
|---|---|---|---|---|---|---|---|---|---|---|---|
| | | abrasive | oxalic | lactic | citrate | citric | (mass %) | acid (mass %) | | electrical | zeta |
| | abrasive | grain | acid | acid | monohydrate | acid | Mw: about | Mw: about | | conductivity | potential |
| Slurry† | grain | (mass %) | (mass %) | (mass %) | (mass %) | (mass %) | 200,000 | 200,000 | pH | (mS/cm) | (mV) |
| A | colloidal | 6.0 | — | — | 0.23 | 0.23 | 0.05 | — | 4.0 | 2.05 | −6.40 |
| | silica A* | | | | | | | | | | |
| B | colloidal | 3.0 | 0.03 | 0.02 | — | — | — | 0.08 | 2.8 | 0.79 | −0.50 |
| | silica B** | | | | | | | | | | |
| C | colloidal | 6.0 | 0.03 | 0.02 | — | — | — | 0.08 | 2.6 | 1.04 | −16.90 |
| | silica A | | | | | | | | | | |
| D | colloidal | 3.0 | 0.03 | 0.02 | — | — | 0.05 | — | 2.7 | 0.91 | ND |
| | silica B | | | | | | | | | | |
| E | colloidal | 3.0 | 0.0045 | 0.002 | — | — | — | 0.08 | 4.2 | 0.08 | ND |
| | silica B | | | | | | | | | | |

†All slurries in water.
*Colloidal silica A: D50 = 104 nm; D10 = 70 nm; D90 = 152 nm; mean value (MV) particle size distribution = 108 nm; D90-to-D10 ratio = 2.17; Purity: Na ppm = 260; BET: 82 m2/g
**Colloidal silica B: D50 = 48 nm; D10 = 34 nm; D90 = 69 nm; MV = 50 nm; D90-to-D10 ratio = 2.03; Purity: Na ppm = 0.02; BET: 78 m2/g
ND = not determined

### Example 2. Five-Day Storage at 80° C.

Each of five compositions from Example 1 was stored in a capped bottle, without stirring, for 5 days at 80° C. Values of particle size distribution (D50, D90, and MV) were measured for the freshly made compositions as well as for the aged compositions by a light scattering method using a particle size measurement instrument (Horiba LA-950).

In other words, the composition 30 mins. after mixing all the components of the polishing composition was measured for the values of particle size distribution (D50, D90, and MV) by a light scattering method using a particle size measurement instrument (Horiba LA-950). Additionally, the composition 5 days (120 hours) after mixing all the components of the polishing composition and standing in a heater at 80° C., followed by cooling to 25° C. by standing at room temperature (25° C.) was measured for the values of particle size distribution (D50, D90, and MV) by a light scattering method using a particle size measurement instrument (Horiba LA-950).

Silicon wafers wholly covered by an oxide film were polished with the freshly made compositions or with the aged compositions, and defects were scanned by a Surfscan® SP2 unpatterned wafer surface inspection tool and reviewed by scanning electron microscopy (SEM) using a Hitachi RS-6000 instrument in order to quantify the number of scratches. A defect with a size >0.13 μm was recorded. Data is shown in Table 2.

(Polishing Conditions)

Polishing apparatus: Mirra-200 mm polishing instrument (Applied Material, Inc.: AMAT)

Polishing pad: polyurethane pad (IC1010: Rohm & Haas)

Pressure: 1.5 psi

Platen rotation speed: 60 rpm

Head (carrier) rotation speed: 60 rpm

Flow rate of polishing composition: 200 ml/min

Polishing time: 60 sec

TABLE 2

| Slur- | D50 (after)/ | D90 (after)/ | MV(after)/ | scratches | scratches |
|---|---|---|---|---|---|
| ry | D50 (before) | D90 (before) | MV(before) | (before) | (after) |
| A | 12.18 | 23.16 | 16.08 | 200 | 1250 |
| B | 1.55 | 1.94 | 1.65 | 30 | 120 |
| C | 1.25 | 1.22 | 1.22 | 200 | 220 |
| D | 1.71 | 1.80 | 1.75 | 30 | 250 |
| E | 3.01 | 3.22 | 3.12 | 30 | 760 |

As indicated in Table 2, the slurries B, C, and D have a ratio of D50(after) to D50(before) of less than 2.0, a ratio of D90(after) to D90(before) of less than 2.0, and a ratio of MV(after) to MV(before) of less than 2.0, indicating that they are good slurries. Additionally, the number of scratches(before) and the number of scratches(after) are significantly low and favorable.

### Example 3. Seven-Day Storage at 25° C.

Each of two compositions from Example 1 was stored in an uncovered beaker, without stirring, under ventilation for 7 days at 25° C. D50, D90, D10, and MV measurements were made as in Example 2. Scratching of the silicon wafers was also assessed as in Example 2. Data is shown in Table 3.

In other words, the composition 30 mins. after mixing all the components composing the polishing composition was measured for the values of the particle size distribution (D₅₀, D₉₀, and MV) by a light scattering method using a particle size measurement instrument (Horiba LA-950). Additionally, the composition 7 days (168 hours) after mixing all the components composing the polishing composition was measured for the values of the particle size distribution (D₅₀/D₉₀/and MV) by a light scattering method using a particle size measurement instrument (Horiba LA-950).

TABLE 3

| | | | | # | # |
|---|---|---|---|---|---|
| Slur- | D50 (after)/ | D90 (after)/ | MV(after)/ | scratches | scratches |
| ry | D50 (before) | D90 (before) | MV(before) | (before) | (after) |
| A | 1.16 | 1.05 | 1.13 | 200 | 320 |
| B | 1.01 | 0.99 | 1.01 | 30 | 80 |

As indicated in Table 3, the slurry B has a ratio of D50(after) to D50(before) of less than 1.15, a ratio of D90(after) to D90(before) of less than 1.05, a ratio of MV(after) to MV(before) of less than 1.15, indicating that it is a good slurry. Additionally, the number of scratches(before) and the number of scratches(after) are significantly low and favorable.

### Example 4. Ten-Day Storage at 55° C.

Four compositions from Example 1 were stored in a capped bottle, without stirring, for 10 days at 55° C. D50, D90, D10, and MV measurements were made as in Example 2. Scratching of silica wafers was also assessed as in Example 2. Data is shown in Table 4.

In other words, the composition at the point of 30 mins. after mixing all the components of the polishing composition was measured for the values of the particle size distribution (D₅₀, D₉₀, and MV) by a light scattering method using a particle size measurement instrument (Horiba LA-950). Additionally, the composition at the time point of 10 days (240 hours) after mixing all the components of the polishing composition and placing in a heater at 55° C., followed by cooling to 25° C. by standing at room temperature (25° C.), was measured for the values of the particle size distribution (D50, D90, and MV) by a light scattering method using a particle size measurement instrument (Horiba LA-950).

TABLE 4

| Slur- | D50 (after)/ | D90 (after)/ | MV(after)/ | scratches | scratches |
|---|---|---|---|---|---|
| ry | D50 (before) | D90 (before) | MV(before) | (before) | (after) |
| A | 6.58 | 13.05 | 8.97 | 200 | 600 |
| B | 1.19 | 1.17 | 1.18 | 30 | 90 |
| C | 1.00 | 1.00 | 1.00 | 200 | 200 |
| D | 1.31 | 1.33 | 1.32 | 30 | 110 |
| E | 2.42 | 2.58 | 2.48 | 30 | 200 |

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims. The present application is based on U.S. Provisional Application Nos. 62/288,340 filed on Jan. 28, 2016, and the disclosure of which is incorporated by reference in its entirety.

1. A polishing composition comprising abrasive grains, an additive, and a water-soluble polymer,
wherein a ratio of D50(after) to D50(before) is less than 2.0,
wherein D50(before) is a value of D50 of particles of the composition when measured before the composition stands for 5 days at 80° C. and D50(after) is a value of D50 of particles of the composition when measured after the composition stands for 5 days at 80° C.

2. The polishing composition of claim 1, wherein the composition has a pH of less than 4.0.

3. The polishing composition of claim 2, wherein the composition has a pH of less than 3.0.

4. The polishing composition of claim 1, wherein the composition has an electrical conductivity of 0.2 to 1.9.

5. The polishing composition of claim 1, wherein the additive is carboxylic acid which may have hydroxyl group.

6. The polishing composition of claim 5, wherein the carboxylic acid which may have hydroxyl group has two or less carboxyl group in the molecule thereof.

7. The polishing composition of claim 5, wherein the carboxylic acid which may have hydroxyl group is any one of lactic acid and oxalic acid.

8. The polishing composition of claim 1, wherein the water-soluble polymer has at least one carboxyl group or polysaccharide consisting of glucose.

9. The polishing composition of claim 8, wherein the polysaccharide consisting of glucose is pullulan, starch, dextrin, cyclodextrin or dextran and the water-soluble polymer having carboxyl group is polycarboxylic acid.

10. The polishing composition of claim 9, wherein the polycarboxylic acid is polyacrylic acid.

11. The polishing composition of claim 1, wherein the abrasive grains comprise colloidal silica.

12. The polishing composition of claim 1, wherein the composition comprises colloidal silica, lactic acid, oxalic acid and polycarboxylic acid and has a pH of less than 4.0.

13. The polishing composition of claim 1, wherein the composition does not comprise at least one kind selected from the group consisting of ammonium salt, citric acid and citric acid salt.
